(19) United States
(12) Patent Application Publication
(10) Pub. No.: US 2026/0190394 A1
(43) Pub. Date: Jul. 2, 2026

(54) TRANSISTOR STRUCTURES WITH SELECTIVE SOURCE/DRAIN CONTACT METALLIZATION

(71) Applicant: Intel Corporation, Santa Clara, CA (US)

(72) Inventors: Guowei Xu, Portland, OR (US); Tao Chu, Portland, OR (US); Kan Zhang, Hillsboro, OR (US); Yang Zhang, Rio Rancho, NM (US); Ting-Hsiang Hung, Beaverton, OR (US); Feng Zhang, Portland, OR (US); Chia-Ching Lin, Portland, OR (US); Chun Wing Yeung, Portland, OR (US); Chung-Hsun Lin, Portland, OR (US); Oleg Golonzka, Beaverton, OR (US); Tahir Ghani, Portland, OR (US)

(73) Assignee: Intel Corporation, Santa Clara, CA (US)

(21) Appl. No.: 19/002,556

(22) Filed: Dec. 26, 2024

(51) Int. Cl. H10D 30/67; H10D 84/01; H10D 84/83

(52) U.S. Cl. CPC H10D 30/6737; H10D 30/6735; H10D 84/0149; H10D 84/832

(57) ABSTRACT

Transistor structures with selectively deposited source/drain contact metallization. Through selective formation of contact metallization, damascene-type patterning of source/drain contact metallization may be avoided so that any differences in topography between transistor structures and adjacent isolation structures do not induce contact metallization shorts or other failures associated over-polishing source/drain contact metallization. In accordance with embodiments, a source/drain contact liner metallization may be deposited and/or retained only within a topographic recess over source/drain semiconductor material. Source/drain contact cap metallization may be then deposited and/or retained only on the contact liner metallization.

### BACKGROUND

For advanced integrated circuits (ICs), stacked field effect transistor (FET) architectures are becoming increasingly complex. Ensuring coplanarity across various elements of transistor structures and intervening transistor isolation structures becomes more difficult as frontend device architectural complexity increases. However, non-coplanarity of structural features hinders damascene-type integration techniques whereby a planarization/polishing process is utilized to confine features, such as source/drain contact metallization features, within topographic depressions. For example, insufficient polishing of source/drain contact metallization features may incompletely define separate features, instead leaving stringers of metallization that may electrically short together two or more features. In other examples, overpolishing to avoid metallization stringers can remove too much material from source/drain contact metallization features and/or from other underlying structures.

Accordingly, damascene-type integration techniques become more difficult and/or less robust with increasing frontend device architectural complexity. Frontend IC architectures and fabrication techniques that can accommodate greater structural nonplanarity and thereby accommodate more complex scaled transistor architectures are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of fabricating transistor structures with selective source/drain contact metallization, in accordance with some embodiments;

FIGS. 2, 3, 4, 5, 6, 7 and 8 are cross-sectional views of transistor structures evolving as the methods illustrated in FIG. 1 are practiced, in accordance with some embodiments;

FIG. 9 illustrates a mobile computing platform and a data server machine employing an IC device including transistor structures with selective source/drain contact metallization, in accordance with some embodiments; and

FIG. 10 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. In one example, two compositions that are substantially the same, have only incidental chemical variation. As another example, composition that is substantially a first constituent means the composition may further include <1% of any other constituent. A composition that is substantially first and second constituents means the composition may further include <1% of any constituent substituted for either the first or second constituent.

In accordance with embodiments herein, transistor source/drain contact metallization is selectively formed within topographic depressions without relying on damascene-type polishing techniques. Accordingly, contact metallization shorts or other failures associated differences in topography between transistor structures and adjacent isolation structures may be avoided. In accordance with exemplary embodiments, a source/drain contact liner metallization may be deposited and/or retained only within a topographic recess over source/drain semiconductor material. Source/drain contact cap metallization may be then selectively deposited on only the contact liner metallization.

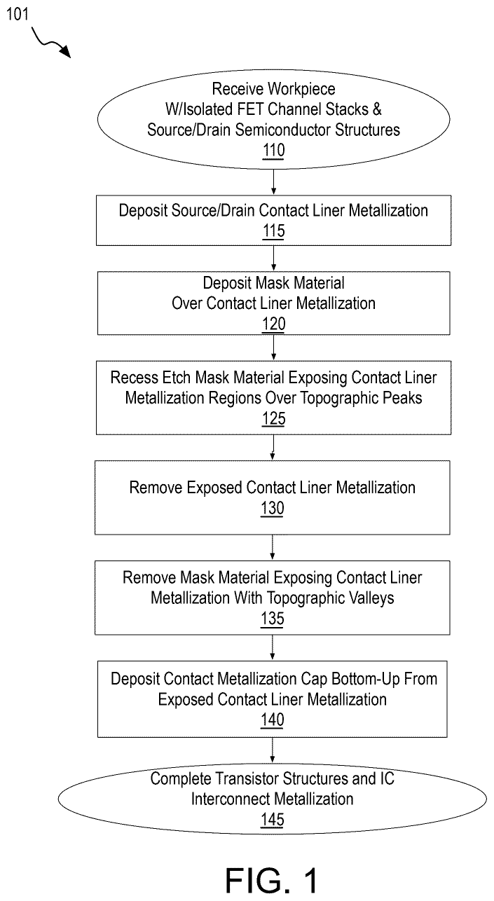

FIG. 1 is a flow diagram illustrating methods 101 for fabricating a transistor structure with selectively formed source/drain contact metallization features, in accordance with some exemplary embodiments. Methods 101 begin at input 110 with receipt of a workpiece including field effect transistor (FET) structures comprising source and drain semiconductor material coupled to channel semiconductor material layers within a channel stack. In some examples, the workpiece received at input 110 comprises a 300-450 mm diameter wafer. The workpiece may include a substantially monocrystalline subfin material and any number of transistor channel material layers over the subfin material. In exemplary embodiments, a transistor isolation structure comprising one or more dielectric materials is between adjacent transistor structures. Depending on the IC manufacturing process, various other transistor features may also be present on the workpiece. For example, transistor gate structures may also be present on the workpiece received at input 110.

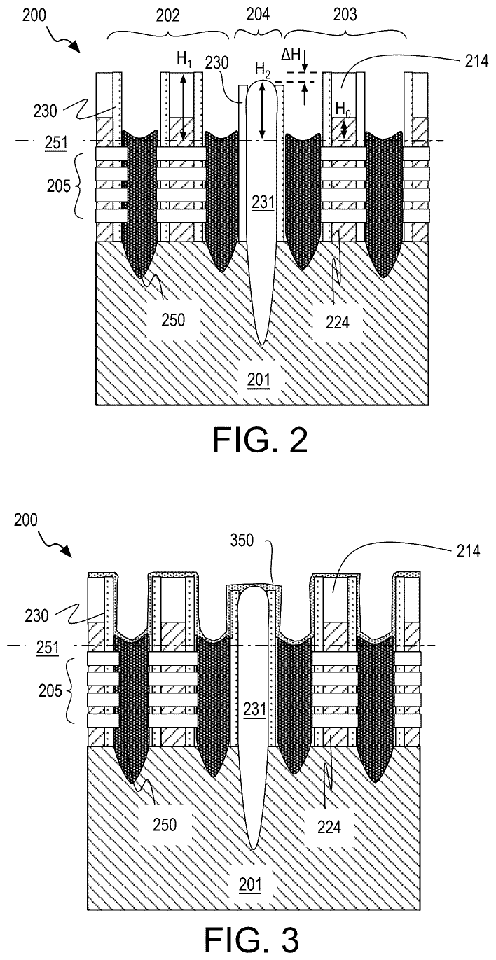

In the example illustrated in FIG. 2, a workpiece comprises IC structures 200, which further comprise a first transistor structure 202 over a subfin semiconductor material 201, a second transistor structure 203 over subfin semiconductor material 201. An intervening transistor isolation structure 204 is between transistor structures 202, 203. In the illustrated example, transistor structure 202 includes a first stack of transistor channel material layers 205. Transistor structure 203 similarly includes a second stack of transistor channel material layers 205. Transistor structure 202 may be associated with a first conductivity type while transistor structure 203 may be associated with a second conductivity type. For example, transistor structure 202 may be an N-type (NMOS) transistor structure while transistor structure 203 may be a P-type (PMOS) transistor structure, or vice versa. In other embodiments, transistor structures 202 and 203 may both be of a same conductivity type (e.g., both N-type or both P-type).

Channel material layers 205 may have any composition suitable for a channel of a field effect transistor (FET). In some examples, channel material layers 205 are substantially pure silicon. In other embodiments, channel material layers 205 comprise germanium (e.g., SiₓGe_{1-X}, GeₓSn_{1-X}, or substantially pure Ge). In some embodiments, channel material layers 205 include a transition metal and a chalcogen. The transition metal may be any transition metal such as any element of groups 4 through 11, the group 3 elements scandium and yttrium, and the inner transition metals (e.g., f-block lanthanide and actinide series). Notable transition metals are molybdenum and tungsten. The chalcogen may be sulfur, selenium, and tellurium. In still other embodiments, channel material layer 205 comprise one or more metals and oxygen (i.e., metal oxide semiconductor), such as, but not limited to, Indium, gallium zinc oxide (IGZO).

Regardless of chemical composition, channel material layers 205 are advantageously crystalline. Although the crystalline semiconductor includes polycrystalline thin film material, in some embodiments channel material layers 205 are substantially monocrystalline. In some examples where channel material layers 205 are substantially pure silicon, the crystallinity of channel material layers 205 is cubic with a top surface having a crystallographic orientation of (100), (111), or (110). However, other crystallographic orientations are also possible. In other examples, channel material layers 205 may be polycrystalline or amorphous, for example in certain metal chalcogen and/or metal oxide embodiments.

As further illustrated in FIG. 2, channel material layers 205 are over a subfin material 201. In exemplary embodiments, subfin material 201 is a portion a (mono)crystalline substrate material. For example, subfin material 201 may be substantially monocrystalline silicon (e.g., with only trace impurities and/or crystal defects). Transistor structures 202, 203 include a sidewall spacer dielectric material 230 protecting underlying channel material. Sidewall spacer dielectric material 230 may comprise a silicon-based dielectric (e.g., SiO₂, Si₃N₄, SiON, etc.). Optionally, adjacent channel material layers 205 may be recess etched, for example with an isotropic etch process selective to the channel semiconductor material, to form a dimple (not depicted) that may then be backfilled with an additional sidewall spacer dielectric material.

Transistor structures 202, 203 further include source/drain semiconductor material 250, which may be impurity doped with donor species or acceptor species depending on whether the transistor structure is a PMOS and NMOS device. In some exemplary embodiments where channel material layers 205 are associated with a PMOS FET structure, source/drain semiconductor material 250 is a Si₁₋ₓGeₓ alloy further including acceptor impurities imparting p-type electrical conductivity. In other exemplary embodiments where channel material layers 205 are associated with an NMOS FET structure, source/drain semiconductor material 250 is substantially pure silicon (i.e., only Group IV element is silicon) further including donor impurities imparting n-type electrical conductivity.

Transistor structures 202, 203 each further comprise a gate structure 224. In exemplary embodiments, gate structure 224 includes a gate material separated from channel material layers 205 by a gate insulator material. Gate structure 224 is between individual ones of channel material layers 205. The gate insulator material may have a relatively high dielectric constant(ε). In some high-K gate dielectric embodiments, the gate insulator material is a metal oxide comprising oxygen and one or more metals, such as, but not limited to, aluminum, hafnium, zirconium, tantalum, or titanium. In other embodiments, gate insulator material is a ferroelectric. In still other embodiments, gate insulator material may be primarily silicon oxide. The gate material may be, or include, a metal such as but not limited to platinum, nickel, molybdenum, tungsten, palladium, gold, alloys thereof, or nitrides such as titanium nitride, tantalum nitride, tungsten silicon nitride, etc. In some embodiments, gate the material includes a work function metal and a fill metal (not depicted).

As further illustrated in FIG. 2, gate structure 224 includes a gate cap material 214, which may be any dielectric material of suitable composition. In some examples, gate cap material 214 is silicon oxide (SiO), silicon nitride (SiN), or silicon oxynitride, (SiON). Although only one layer is illustrated in FIG. 2, gate cap material 214 may comprise one or more material layers having a total thickness, for example in the range of 10-30 nm. Relative to a reference plane 251, which is parallel to the surface plane of subfin material 201 and coincident with a top surface of source/drain semiconductor material 250, a top surface of gate material 224 has a height H₀ while a top surface of gate cap material 214 has height H₁. Although implementations may vary, in some examples height H₁ is 30-50 nm. Height H₀ may also vary, for example ranging from 10-25 nm.

FIG. 2 further illustrates transistor isolation structure 204, which may include one or more layers of one or more dielectric materials. In the illustrated example, isolation structure 204 includes sidewall spacer dielectric material 230 and a trench dielectric material 231. Trench dielectric material 231 may have any suitable composition, such as, but not limited to, one or more of SiO₂, Si₃N₄, SiON, etc. As shown, one body of source/drain semiconductor material 250 for each of transistor structures 202, 203 is in contact with isolation structure 204, and more specifically sidewall spacer dielectric material 230. Relative to reference plane 251, a top surface of isolation structure 204 has a height H₂. As illustrated, height H₂ and height H₁ are not equal and therefore top surface of isolation structure 204 is non-coplanar with the top surface of the gate structure (i.e., top surface of gate cap 214). Although implementations may vary, in some examples height H₂ differs from height H₁ (i.e., ΔH) by at least 5 nm and can be 10 nm, or more.

In view of the differences in heights H₁ and H₂, a first contact metallization feature that might be formed within the recess over a body of source/drain semiconductor material 250 on one side of isolation structure 204 would be difficult to separate from a second contact metallization feature that would be formed within the recess over another body of source/drain semiconductor material 250 on a second side of isolation structure 204. For example, a polish process that exposes a top surface of gate cap 214 would not expose a top surface of isolation structure 204. Yet, a polish process that exposes the lower top surface of isolation structure 204 would overpolish gate cap material 214 by at least the height differential ΔH.

Accordingly, methods 101 (FIG. 1) instead further entail selective source/drain contact metallization, which continues at block 115 where one or more layers of contact metallization liner material are deposited. The contact metallization liner material may be deposited selectively only upon source/drain semiconductor material, or non-selectively such that that the contact metallization liner material is formed over all transistor structures (e.g., gate structures, source/drain semiconductor structures, etc.) and over intervening transistor isolation structures. The contact metallization liner material deposited at block 115 may include an interfacial layer that will provide a low-resistance ohmic or tunneling semiconductor-metal junction with underlying source/drain semiconductor material. The contact metallization liner material may also include a nucleation surface layer over the interfacial layer that promotes selective deposition of one or more layers of contact metallization cap material that form a low-resistance contact metallization feature or body that does not require further definition through damascene-type processing.

FIG. 3 illustrates a non-selective deposition of contact metallization liner material 350. In some examples, contact metallization liner material 350 includes an interface material layer comprising a first metal in direct contact with source/drain semiconductor material 250. An interface material layer may be very thin, for example less than 5 nm, and in some embodiments 1-2 nm. Although the interface material may be a pure metal or metal alloy, the interface material layer may also comprise one or more of nitrogen (N) or carbon (C). In some examples, the interface material layer comprises one or more of tungsten (W), titanium (Ti). In other examples, the interface material layer comprises one or more of tungsten nitride (WNₓ), or titanium nitride (TiNₓ). In other examples, the interface material layer comprises one or more of tungsten carbide (WCₓ), or titanium carbide (TiCₓ). In still other examples, the interface material layer comprises one or more of tungsten carbo-nitride (WCₓN_{y}), or titanium carbo-nitride (TiCₓN_{y}). For some embodiments where source/drain semiconductor material 250 comprises silicon, the interface material layer may react with the source/drain silicon, forming a metal-silicide (e.g., TiSiₓ).

Contact metallization liner material 350 may further comprise a nucleation material layer suitable for supporting a subsequent selective metal deposition process. A nucleation material layer may also be very thin, for example less than 5 nm, and in some embodiments 1-3 nm. In exemplary embodiments, the nucleation material layer comprises one or more metals absent from the interface material layer. The nucleation material layer may be a pure metal, metal alloy, or may also comprise one or more of nitrogen or carbon. In some examples where the interface material layer comprises titanium or another metal, the nucleation material layer comprises tungsten, and may further comprise nitrogen (WNₓ), carbon (WCₓ) or both nitrogen and carbon (WCₓN_{y}).

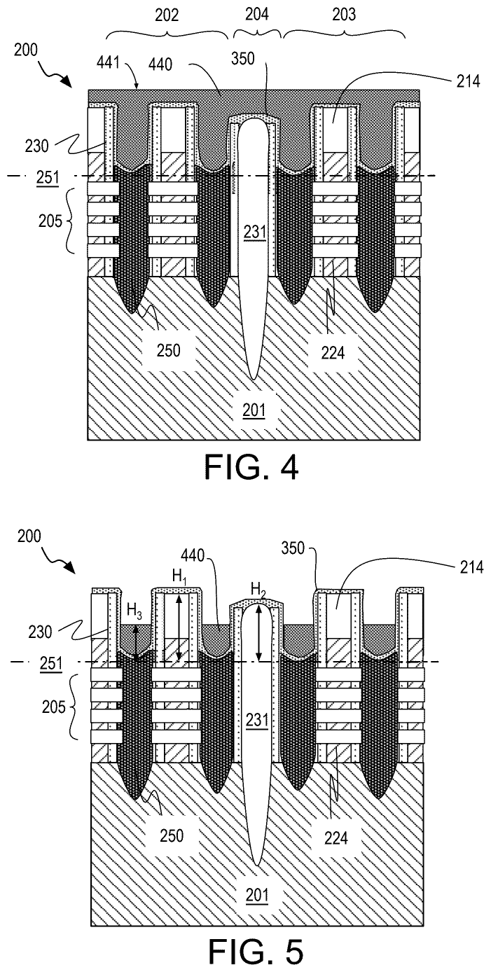

For embodiments where contact metallization liner material are deposited non-selectively at block 115 (FIG. 1), methods 101 continue with patterning the contact metallization liner material in preparation for a subsequent selective deposition of one or more layer of contact metallization cap material. Although contact metallization liner material may be patterned with any technique, methods 101 illustrate exemplary embodiments that leverage topography of the transistor structures. At block 120, a mask material is deposited over the contact metallization liner layers, for example with a process that planarizes a top surface of the mask material. FIG. 4 further illustrates an example where a mask material 440 has been deposited over transistor structures 202, 203 and over isolation structure 204. Mask material 440 backfills recesses over source/drain semiconductor material 250 between gate caps 214 and isolation structure 204. As shown, mask material 440 is deposited to a sufficient thickness for mask surface 441 to be nearly planarized over a length on the scale of transistor structures 202, 203. Although the composition of mask material 440 may vary with implementation, in some embodiments mask material 440 is a carbon-based inorganic material that may be deposited, for example with CVD process. In other embodiments mask material 440 is an organic material that may be deposited, for example with a spin-on process, or the like.

Returning to FIG. 1, methods 101 continue at block 125 where the substantially planar top surface of the mask material deposited at block 120 is recess etched, which exposes portions of the contact metallization liner material over underlying topographic peaks. In the example illustrated in FIG. 5, mask material 440 has been etched back, recessing mask material top surface 441 to a height H₃ above reference plane 251. Although recessed mask height H₃ may vary with implementation, height H₃ is less than both height H₁ and height H₂ such that portions of contact metallization liner material 350 over top surfaces of both gate cap 214 and isolation structure 204 are exposed.

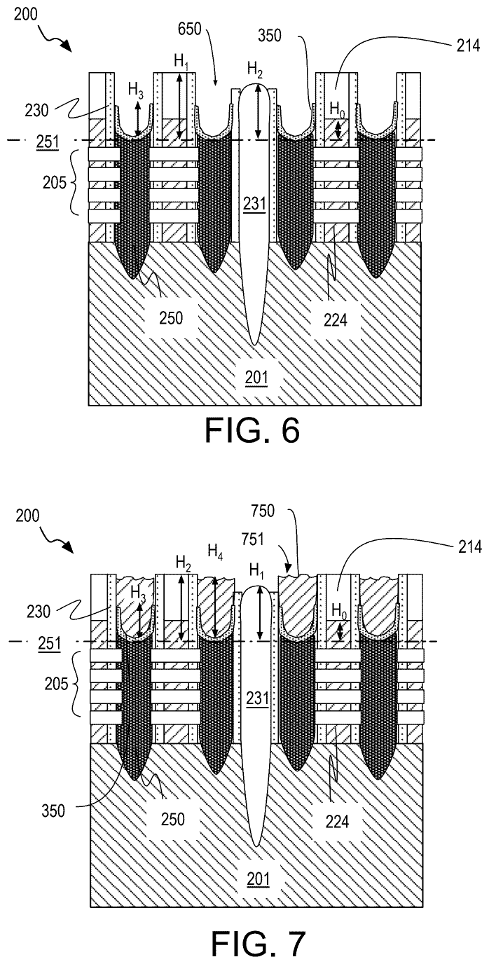

Returning to FIG. 1, methods 101 continue at block 130 where exposed portions of the contact metallization liner layers are removed, for example with one or more etch processes suitable for the chemical compositions of the contact metallization liner material(s). Mask material remaining within topographic recesses is then stripped at block 135 with any process suitable for the composition of the mask material. In the example illustrated in FIG. 6, the continuous layer of contact metallization liner material 350 has been etched into separate bodies or features of contact metallization liner material 350 fully contained within recesses 650 over source/drain semiconductor material 250. Top surfaces of trench dielectric material 231 and gate cap material 214 are now substantially free of contact metallization liner material 350. Similarly, contact metallization liner material 350 has been removed from an upper portion of sidewall spacer dielectric material 230, leaving contact metallization liner material 350 adjacent to a lower portion of sidewall spacer dielectric 230 having approximately the recess height H₃. Notably, height H₃ is significantly less than height H₁, which indicates contact metallization liner material 350 has been etched back rather than removed through a polish process that would result in contact metallization liner material 350 having nearly height H₁. As illustrated, recess height H₃ is significantly larger than a thickness of contact metallization liner material 350. For examples where contact metallization liner material 350 is around 5 nm and recess height H₃ is 10-25 nm, height H₃ is 2-5 times the thickness of contact metallization liner material 350.

Returning to FIG. 1 after patterning (or selective deposition) of a contact metallization liner material, methods 101 continue at block 140 where discrete bodies or features of contact metallization cap material are selectively deposited upon the distinct bodies or features of contact metallization liner material. In some examples, block 140 comprises a selective chemical vapor deposition (CVD) or atomic layer deposition (ALD) process. In some exemplary embodiments where contact metallization liner material comprises a tungsten-based nucleation layer material, a tungsten-based metallization cap material is selectively deposited with a CVD or ALD process. Such deposition processes advantageously utilize fluorine-free precursors, and in some specific examples utilize tungsten chloride (WCl₆) as a precursor to achieve much higher deposition rates on a tungsten-based nucleation material surfaces than on dielectric material surfaces. In further embodiments, the selective deposition process may be cyclical, iteratively depositing and removing atomic layers of tungsten-based metallization cap material such that essentially no metallization cap material forms on dielectric material surfaces. The fluorine-free precursors selectively form contact metallization cap material with little (e.g., less than 5e14 atoms/cm²) to no fluorine contamination in the film stack, which is advantageous, at least in part, because fluorine contamination can increase resistivity of the material and is reactive with other elements, such as titanium.

In the example illustrated in FIG. 7, bodies of contact metallization cap material 750 have been selectively formed upon bodies of contact metallization liner material 350. In exemplary embodiments where contact metallization liner material 350 comprises a tungsten-based nucleation material, contact metallization cap material 750 is also tungsten-based. In exemplary embodiments, contact metallization cap material 750 is advantageously predominantly tungsten, and more advantageously substantially pure tungsten. Although contact metallization cap material 750 may have trace impurities associated with the material deposition process, in exemplary embodiments metallization cap material 750 may be substantially free of fluorine (F). For example, fluorine (F) within metallization cap material 750 is advantageously below 5e18 atoms/cm³, more advantageously below 5e17 atoms/cm³, for example as determined through a sputtering secondary ion mass spectrometry (SIMS) depth profiling technique. Indeed, F content in metallization cap material 750 may even be undetectable with such a SIMS technique. In further examples, F dosage within metallization cap material 750 is advantageously less than 1e15 atoms/cm², and more advantageously less than 5e14 atoms/cm², for example as determined by integrating the area beneath a SIMS F concentration curve. The absence of fluorine from contact metallization cap material 750 is indicative of a selective deposition process employing one or more fluorine-free precursors in accordance with embodiments herein.

Resulting from a bottom-up selective growth process, contact metallization cap material 750 has a top surface 751 with a greater average surface roughness (Rₐ) than top surfaces of trench dielectric material 231 and gate cap material 214. Although the average roughness of contact metallization cap material surface 751 may vary, in some embodiments it is at least twice that of trench dielectric material 231 and/or gate cap material 214 as determined, for example, through transmission electron microscopy (TEM) analysis of peak and valley measurements for each surface/interface region.

Although contact metallization cap material 750 may be deposited to any height, in exemplary embodiments contact metallization cap material 750 is deposited to a height H₄ (e.g., relative to reference plane 251) that is least equal to height H₃ that contact metallization liner material 350 extends sidewall spacer dielectric material 230. In the illustrated embodiments, contact metallization cap material 750 has a height H₄ that exceeds height H₃. For embodiments where height H₄ is between height H₃ and height H₁, greater surface roughness cap material surface 751 will be retained as a permanent feature of transistor structures 202, 203 as a result of the deposition technique and non-coplanarity between these top surfaces. However, in alternative embodiments where contact metallization cap material is deposited to a height H₄ that initially exceeds height H₁, a subsequent polish may be performed to planarize cap material surface 751 with a surface of gate cap material 214, in which case the illustrated greater surface roughness and non-coplanarity of contact metallization cap material 750 and gate cap 214 may not be retained as a permanent feature of transistor structures 202, 203. As further illustrated in FIG. 7, in some embodiments, height H₄ is greater than the trench dielectric height H₁. Non-coplanarity between heights H₄ and H₁ is also indicative selective deposition of contact metallization cap material 750.

Returning to FIG. 1, methods 101 complete at output 145 where transistor structures may be completed accordingly to any known techniques to arrive at any architecture known to be suitable for FETs. Gate, source and drain terminals of the transistor structures may then be interconnected into integrated circuitry according to any known techniques. For example, any number of levels of backend metallization levels may be fabricate over the transistor structures. The workpiece may then be singulated into individual die, chips, or chiplets according to any suitable techniques.

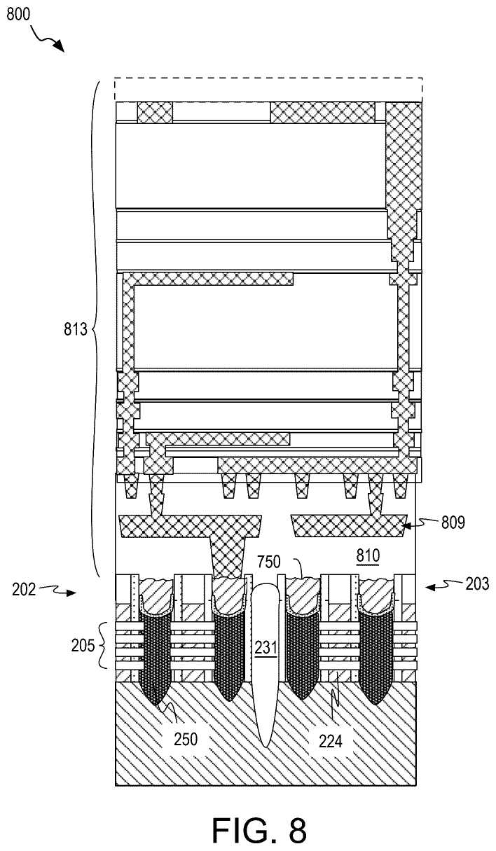

In the example illustrated in FIG. 8, an IC die structure 800 includes frontside transistor interconnect metallization structure 813, which further includes one or more interconnect metallization levels 809 embedded in dielectric material 810. Interconnect metallization levels 809 are interconnected to transistor structures 202, 203. In the illustrated example, a frontside metallization feature is in direct contact with a contact metallization cap material 750. Other frontside metallization features may similarly be electrically coupled to other bodies of contact metallization cap material 750 and/or gate structure 224. Although not illustrated, backside interconnect metallization levels may be similarly fabricated on an opposite side of transistor structures 202, 203. For example, subfin material 201 may be replaced with dielectric material and interconnect metallization levels.

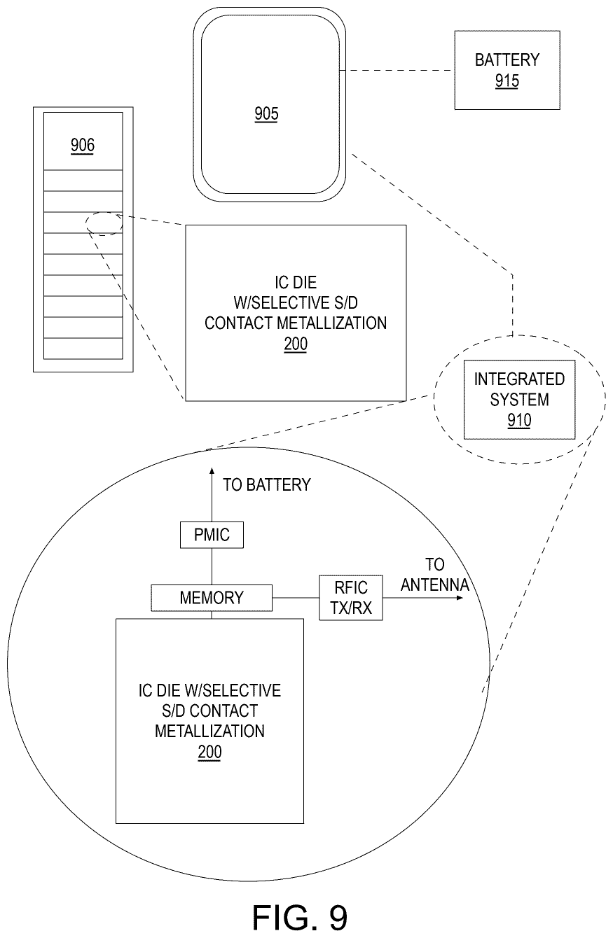

The transistor structures and IC die structures described above may be employed in a wide range of IC devices and further integrated in a wide range of computer-based applications. FIG. 9 illustrates a mobile computing platform 905 and a server machine 906, each employing IC die structure 200 including transistors with selectively deposited source/drain contact metallization, for example as described elsewhere herein.

Server machine 906 may be any commercial server, for example including any number of high-performance computing platforms disposed within a rack and networked together for electronic data processing, which in the exemplary embodiment includes IC structure 200 comprising transistors with selectively deposited source/drain contact metallization, for example as described elsewhere herein. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), an integrated system 910, and a battery 915.

As illustrated in the expanded view of FIG. 9, one or more of a power management integrated circuit (PMIC) or RF (wireless) integrated circuit (RFIC) including a wideband RF (wireless) transmitter and/or receiver may be further coupled to IC die structure 200. A PMIC may perform battery power regulation, DC-to-DC conversion, etc., and so has an input coupled to battery 915 and an output providing a current supply to other functional modules. An RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

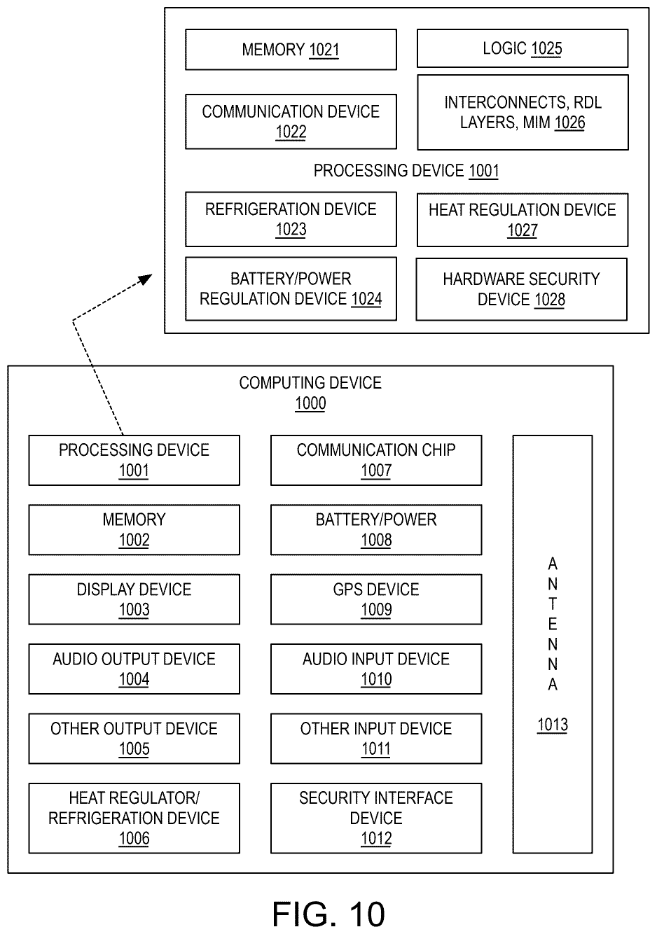

FIG. 10 is a block diagram of a cryogenically cooled computing device 1000 in accordance with some embodiments. For example, one or more components of computing device 1000 may include transistors selectively deposited source/drain contact metallization, for example as described elsewhere herein. A number of components are illustrated in FIG. 10 as included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1021, a communication device 1022, a refrigeration/active cooling device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1001 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1001 includes memory that shares a die with processing device 1001. This memory may be used as cache memory and may include embedded dynamic random-access memory (eDRAM) or spin transfer torque magnetic random-access memory (STT-M RAM).

Computing device 1000 may include a heat regulation/refrigeration device 1006. Heat regulation/refrigeration device 1006 may maintain processing device 1001 (and/or other components of computing device 1000) at a predetermined low temperature during operation. This predetermined low temperature may be any temperature discussed elsewhere herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications terminating at antenna 1013, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000, as known in the art.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection. In some examples, security interface device 1012 comprises OTP ROM further including a via MIM fuse, for example as described elsewhere herein.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments described above, but can instead be practiced with modification and alteration without departing from the scope of the appended claims. For example, the above embodiments may include specific combinations of features as further provided below.

In first examples, an apparatus comprises an isolation structure, and a transistor structure adjacent to the isolation structure. The transistor structure comprises a stack of channel material features, a gate electrode structure wrapped around a center portion of the material features, and source and drain semiconductor materials coupled to end portions of the channel material features. The transistor structure comprises a contact metallization in contact with the source and drain semiconductor materials. The contact metallization comprises a body of cap metal comprising predominantly tungsten, and wherein the body of cap metal is substantially free of fluorine.

In second examples, for any of the first examples the contact metallization further comprises a body of liner metal between the body of cap metal and the source and drain semiconductor materials. The body of liner metal extends up a sidewall of the isolation structure by a first height from a plane passing through an interface between the body of liner metal and the source and drain semiconductor material. A top surface of the body of cap metal is a second height from the interface, and wherein the second height exceeds the first height.

In third examples, for any of the second examples the top surface of the body of cap metal is non-coplanar with the top surface of the isolation structure.

In fourth examples, for any of the third examples the top surface of the isolation structure is a third height from the interface, and wherein the third height is lower than the second height.

In fifth examples, for any of the second through fourth examples the top surface of the body of cap metal has a greater average roughness than a top surface of the isolation structure.

In sixth examples, for any of the second through fifth examples the body of liner metal comprises one or more metals other than W, and at least one of N or C.

In seventh examples, for any of the sixth examples the body of liner metal comprises Ti.

In eighth examples, an integrated circuit (IC) structure comprises an isolation dielectric structure, and a first transistor structure. The first transistor structure comprises a first gate around a plurality of transistor channel layers in a first stack, a first source or drain semiconductor material coupled to the channel layers in the first stack and in contact with a first side of the isolation dielectric structure. The first transistor structure comprises a first body of contact liner metallization in contact with the first source or drain semiconductor material and extending up a sidewall of the isolation dielectric structure to a first height over the first source or drain semiconductor material. The first transistor structure comprises a first body of contact cap metallization in contact with the first body of contact liner metallization, a top surface of the first body of contact cap metallization at a second height, greater than the first height, over the first source or drain semiconductor material.

In ninth examples, for any of the eighth examples the IC structure further comprises a second transistor structure. The second transistor structure comprises a second gate around a plurality of transistor channel layers in a second stack, and a second source or drain semiconductor material coupled to the channel layers in the second stack and in contact with a second side of the isolation dielectric structure. The second transistor structure comprises a second body of contact liner metallization in contact with the second source or drain semiconductor material and extending up a sidewall of the isolation dielectric structure to a third height over the second source or drain semiconductor material, and a second body of contact cap metallization in contact with the second body of contact liner metallization, a top surface of the second body of contact cap metallization at a fourth height, greater than the third height, over the second source or drain semiconductor material.

In tenth examples, for any of the ninth examples the first height is substantially equal to the third height, and wherein second height is substantially equal to the fourth height.

In eleventh examples, for any of the ninth through tenth examples the first and second bodies of contact cap metallization comprise predominantly W and are substantially free of F.

In twelfth examples, for any of the ninth through eleventh examples the first and second bodies of contact liner metallization is a metal nitride, metal carbide, or metal carbo-nitride.

In thirteenth examples, for any of the ninth through twelfth examples the top surfaces of the first and second bodies of contact cap metallization are non-coplanar with the top surface of the isolation dielectric structure.

In fourteenth examples, for any of the thirteenth examples the top surface of the isolation dielectric structure is below the top surfaces of the first and second bodies of contact cap metallization.

In fifteenth examples, for any of the eighth through fourteenth examples the top surface of the bodies of cap metal have a greater average roughness than a top surface of the isolation dielectric structure.

In sixteenth examples, a method comprises receiving a workpiece comprising a channel material layer stack adjacent to a source and drain semiconductor material between the channel material layer stack and an isolation dielectric structure. The method comprises forming contact metallization on the source and drain semiconductor material selectively over the isolation dielectric structure.

In seventeenth examples, for any of the sixteenth examples forming the contact metallization comprises depositing W with one or more precursors comprising W and a halogen other than F.

In eighteenth examples, for any of the seventeenth examples the precursors comprise W and Cl.

In nineteenth examples, for any of the sixteenth through eighteenth examples forming the contact metallization comprises forming a first metallization layer on the source and drain semiconductor material, and depositing the W selectively upon the first metallization layer.

In twentieth examples, for any of the nineteenth examples the method further comprises depositing a mask material over the first metallization layer, planarizing the mask material, recess etching the mask material after the planarizing, the recess etching removing the mask material from the isolation dielectric structure, removing a portion of the first metallization layer from over the isolation dielectric structure, exposing a remainder of the first metallization by removing a remainder of the mask material, and depositing the W selectively upon the remainder of the first metallization layer.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An apparatus, comprising:
an isolation structure; and
a transistor structure adjacent to the isolation structure, wherein the transistor structure comprises:
a stack of channel material features;
a gate electrode structure wrapped around a center portion of the material features; and
source and drain semiconductor materials coupled to end portions of the channel material features; and
a contact metallization in contact with the source and drain semiconductor materials, wherein the contact metallization comprises a body of cap metal comprising predominantly tungsten, and wherein the body of cap metal has a fluorine content below 5e17 atoms/cm³.

2. The apparatus of claim 1, wherein:
the contact metallization further comprises a body of liner metal between the body of cap metal and the source and drain semiconductor materials; and
the body of liner metal extends up a sidewall of the isolation structure by a first height from a plane passing through an interface between the body of liner metal and the source and drain semiconductor material; and
a top surface of the body of cap metal is a second height from the interface, and wherein the second height exceeds the first height.

3. The apparatus of claim 2, wherein the top surface of the body of cap metal is non-coplanar with the top surface of the isolation structure.

4. The apparatus of claim 3, wherein the top surface of the isolation structure is a third height from the interface, and wherein the third height is lower than the second height.

5. The apparatus of claim 2, wherein the top surface of the body of cap metal has a greater average roughness than a top surface of the isolation structure.

6. The apparatus of claim 2, wherein the body of liner metal comprises one or more metals other than W, and at least one of N or C.

7. The apparatus of claim 6, wherein the body of liner metal comprises Ti.

8. An integrated circuit (IC) structure, comprising:
an isolation dielectric structure; and
a first transistor structure, wherein:
the first transistor structure, comprises:
a first gate around a plurality of transistor channel layers in a first stack;
a first source or drain semiconductor material coupled to the channel layers in the first stack and in contact with a first side of the isolation dielectric structure;
a first body of contact liner metallization in contact with the first source or drain semiconductor material and extending up a sidewall of the isolation dielectric structure to a first height over the first source or drain semiconductor material; and
a first body of contact cap metallization in contact with the first body of contact liner metallization, a top surface of the first body of contact cap metallization at a second height, greater than the first height, over the first source or drain semiconductor material.

9. The IC structure of claim 8, further comprising a second transistor structure, wherein the second transistor structure comprises:
a second gate around a plurality of transistor channel layers in a second stack; and
a second source or drain semiconductor material coupled to the channel layers in the second stack and in contact with a second side of the isolation dielectric structure;
a second body of contact liner metallization in contact with the second source or drain semiconductor material and extending up a sidewall of the isolation dielectric structure to a third height over the second source or drain semiconductor material; and
a second body of contact cap metallization in contact with the second body of contact liner metallization, a top surface of the second body of contact cap metallization at a fourth height, greater than the third height, over the second source or drain semiconductor material.

10. The IC structure of claim 9, wherein first height is substantially equal to the third height, and wherein second height is substantially equal to the fourth height.

11. The IC structure of claim 9, wherein the first and second bodies of contact cap metallization comprise predominantly W with a F content below 5e14 atoms/cm².

12. The IC structure of claim 9, wherein the first and second bodies of contact liner metallization is a metal nitride, metal carbide, or metal carbo-nitride.

13. The IC structure of claim 9, wherein the top surfaces of the first and second bodies of contact cap metallization are non-coplanar with the top surface of the isolation dielectric structure.

14. The IC structure of claim 13, wherein the top surface of the isolation dielectric structure is below the top surfaces of the first and second bodies of contact cap metallization.

15. The IC structure of claim 8, wherein the top surface of the bodies of cap metal have a greater average roughness than a top surface of the isolation dielectric structure.

16. A method comprising:
receiving a workpiece comprising a channel material layer stack adjacent to a source and drain semiconductor material between the channel material layer stack and an isolation dielectric structure; and
forming contact metallization on the source and drain semiconductor material selectively over the isolation dielectric structure.

17. The method of claim 16, wherein forming the contact metallization comprises depositing W with one or more precursors comprising W and a halogen other than F.

18. The method of claim 17, wherein the precursors comprise W and Cl.

19. The method of claim 16, wherein forming the contact metallization comprises:
forming a first metallization layer on the source and drain semiconductor material; and
depositing the W selectively upon the first metallization layer.

20. The method of claim 19, further comprising:
depositing a mask material over the first metallization layer;
planarizing the mask material;
recess etching the mask material after the planarizing, the recess etching removing the mask material from the isolation dielectric structure;
removing a portion of the first metallization layer from over the isolation dielectric structure;
exposing a remainder of the first metallization by removing a remainder of the mask material; and
depositing the W selectively upon the remainder of the first metallization layer.
